(19) United States
(12) Patent Application Publication
(10) Pub. No.: US 2003/0213975 A1
(43) Pub. Date: Nov. 20, 2003

(54) Semiconductor device

(75) Inventors: Yutaka Hirose, Kyoto (JP); Kaoru Inoue, Shiga (JP); Yoshito Ikeda, Osaka (JP)

Correspondence Address: Jack Q. Lever, Jr., McDERMOTT, WILL & EMERY, 600 Thirteenth Street, N.W., Washington, DC, 20005-3096, US

(73) Assignee: MATSUSHITA ELECTRIC INDUSTRIAL CO, LTD.

(21) Appl. No.: 10/417,138

(22) Filed: Apr. 17, 2003

(30) Foreign Application Priority Data
May 17, 2002 (JP) 2002-142410

(51) Int. Cl. H01L 31/0328

(52) U.S. Cl. 257/194

(57) ABSTRACT

A semiconductor device includes an insulating oxide layer formed by oxidizing a nitride semiconductor and an electrode formed of a conductive metal oxide on the insulating oxide layer.

### BACKGROUND OF THE INVENTION

The present invention relates to a semiconductor device in which a nitride semiconductor is used for an active layer and which includes an insulated gate.

FIG. 10 is the cross-sectional view of a conventional semiconductor device. More specifically, FIG. 10 illustrates a cross-sectional structure of an MOS field effect transistor (MOSFET) in which a Group III nitride semiconductor is used for an active layer.

As shown in FIG. 10, a buffer layer 2 of aluminum nitride (AlN), a channel layer 3 of gallium nitride (GaN), and a carrier supply layer 4 of n-type aluminum gallium nitride (AlGaN) are formed in this order on a substrate 1 of sapphire. On the substrate 1 on which the buffer layer 2, the channel layer 3 and the carrier supply layer 4 are formed, an isolation insulating film 5 is formed so that transistor regions are separated from each other. An insulating oxide layer 6 is formed on the carrier supply layer 4 located in each of the transistor regions by oxidizing a nitride semiconductor, and a metal gate electrode 7 is formed on the insulating oxide layer 6. Source/drain electrodes 8 are formed on both sides of the metal gate electrode 7 on the carrier supply layer 4 so as to be in ohmic contact with the carrier supply layer 4.

In this structure, a potential well is created in part of the upper portion of the channel layer 3 located in the vicinity of the heterointerface between the channel layer 3 and the carrier supply layer 4 to be a two-dimensional electron gas layer which has very high electron mobility. Accordingly, the MOSFET of FIG. 10 is a high electron mobility transistor (HBEMT) with high-speed transistor characteristics.

In the conventional semiconductor MOSFET, however, a metal film is deposited directly on the insulating oxide layer 6 obtained by oxidizing the nitride semiconductor itself to form the metal gate electrode 7. This causes the following problem. That is, an oxidation-reduction reaction occurs between the metal gate electrode 7 and the insulating oxide layer 6, and therefore the insulating oxide layer 6, i.e., an gate insulating film, is reduced while the metal electrode 7 is oxidized. As a result, oxygen vacancies (i.e., vacancies resulting from elimination of oxygen) are created in the gate insulating film, and thus electric properties of the interface between the electrode and the insulating film (which will be herein referred to as an “insulating film-electrode interface”) become unstable and also gate leakage current is increased.

### SUMMARY OF THE INVENTION

In view of the above-described problem, an object of the present invention is to provide a semiconductor device which includes a gate insulating film formed by oxidizing a nitride semiconductor and in which electric properties of an insulating film-electrode interface are stabilized while the generation of leakage current is also prevented.

To achieve this object, a semiconductor device according to the present invention includes: an insulating oxide layer formed by oxidizing a nitride semiconductor; and an electrode formed of a conductive metal oxide on the insulating oxide layer.

According to the present invention, the inventive semiconductor device has an insulated gate structure in which an insulating oxide layer formed by oxidizing a nitride semiconductor itself is used as a gate insulating film. In the insulated gate structure, a gate electrode is formed of a conductive metal oxide. More specifically, a metal contained in the gate electrode has been already oxidized, and thus it is possible to prevent a metal oxide (e.g., Ga oxide or Al oxide) forming the gate insulating film from being reduced by an electrode material. As a result, defects in the gate insulating film, such as oxygen vacancies, which would be created if a metal film were deposited directly on the insulating oxide layer to be a gate insulating film, i.e., the gate insulating oxide film, are not created. Accordingly, the generation of leakage current due to such defects can be prevented while electric characteristics of the insulating film-electrode interface can be stabilized. Therefore, it is possible to improve the reliability of the gate insulating film.

In the inventive semiconductor, the conductive metal oxide is preferably any one of indium oxide, indium-tin alloy oxide (tin-doped indium oxide), and rhodium oxide. More specifically, each of these metal oxides is conductive and thus can be used as an electrode material. Also, since a metal contained in each of the metal oxides has been already oxidized, the gate insulating oxide film will not be reduced in forming a gate electrode. Moreover, since the oxidation state (i.e., the oxidation number) of the metal contained in each of the metal oxides is the same as that of a metal (e.g., Al, Ga or In) contained in the gate insulating oxide film, the unit cell structure of a crystal of the metal oxide is the same as that in the gate insulating oxide film. Accordingly, the chemical and structural affininities between the gate electrode formed of any one of the metal oxides and the gate insulating oxide film, i.e., between the metal oxide electrode and the gate insulating oxide film, are increased, and thus no oxygen vacancies, no interstitial metal atoms or the like are created in the vicinity of the interface between the gate insulating film and the gate electrode. Therefore, a chemically stable and highly reliable gate structure with small leakage current can be achieved.

In the inventive semiconductor, the conductive metal oxide is preferably any one of iridium oxide, ruthenium oxide, and tin oxide. More specifically, each of these metal oxides is conductive and thus can be used as an electrode material. Also, since a metal contained in the metal oxide has been already oxidized, the gate insulating oxide film is not reduced in forming a gate electrode. Note that the oxidation state (i.e., the oxidation number) of the metal contained in each of the metal oxides differs from that of a metal (e.g., Al, Ga or In) contained in the gate insulating oxide film and the unit cell structure of a crystal of the metal oxide also differs from that in the gate insulating oxide film. However, the gate electrode made of any one of the metal oxides has excellent oxidation resistance, and also functions as a diffusion barrier against interstitial metal atoms that may be created in part of the gate insulating film located in the vicinity of the interface between the gate insulating film and the gate electrode. Thus, even if interstitial metal atoms are created due to a reduction reaction in the gate insulating oxide film, the metal atoms do not diffuse but stay within the gate insulating oxide film, and are finally re-oxidized. Therefore, a chemically stable and highly reliable gate structure with small leakage current can be achieved.

The inventive semiconductor device may further include a metal layer formed on the electrode. In such a case, if the metal layer is made of a precious metal such as platinum, palladium, iridium, ruthenium, or rhodium, the following effects can be attained. More specifically, since these precious metals have oxidation resistance, the occurrence of an oxidation-reduction reaction can be prevented between the metal layer and the metal oxide electrode, i.e., between the metal electrode and the metal oxide electrode in forming the metal layer. Thus, a fine interface is formed between the metal electrode and the metal oxide electrode. Accordingly, it is possible to avoid the situation in which the metal oxide electrode is reduced by the metal electrode and then the reduced metal oxide electrode is re-oxidized by the gate insulating oxide layer. In other words, it is possible to avoid the situation in which the gate insulating oxide layer is reduced by the metal oxide electrode. Therefore, a highly reliable multilayer gate structure with small leakage current can be achieved.

In the inventive semiconductor device that includes first and second nitride semiconductor layers, the insulating oxide layer is preferably formed by oxidizing the second nitride semiconductor layer which is formed on the first nitride semiconductor layer and whose oxidation speed is higher than that of the first semiconductor layer. In this manner, the insulating oxide layer is formed on the first nitride semiconductor layer by oxidizing the second nitride semiconductor layer itself. Thus, the film quality of the insulating oxide layer, i.e., the film quality of the gate insulating film, is improved while the contact interface between the insulating oxide layer and the first nitride semiconductor layer thereunder becomes very clean. In addition, the oxidation speed of the second semiconductor layer that is to be the gate insulating oxide film is higher than that of the first nitride semiconductor layer formed under the second nitride semiconductor layer. In other words, the oxidation speed of the first semiconductor layer is lower than that of the second nitride semiconductor layer. Accordingly, the first nitride semiconductor layer is hardly oxidized in oxidizing the second nitride semiconductor layer. Therefore, only the second nitride semiconductor layer can be selectively oxidized in a simple manner when the insulating oxide layer is formed.

The first nitride semiconductor layer preferably contains aluminum (Al). For example, aluminum gallium nitride (AlGaN) obtained by adding aluminum to gallium nitride (GaN) that is a typical nitride semiconductor material has a lower oxidation speed than that of gallium nitride. Thus, when AlGaN is used as a material for the first nitride semiconductor layer and GaN is used as a material for the second nitride semiconductor layer, the first nitride semiconductor layer is hardly oxidized in forming the insulating oxide layer. Furthermore, the energy gap of AlGaN is larger than that of GaN and thus the first nitride semiconductor layer can be used as a potential barrier layer.

It is also preferable that the inventive semiconductor device further includes a third nitride semiconductor layer having a smaller energy gap than that of the first nitride semiconductor layer under the first nitride semiconductor layer, i.e., between the substrate and the first nitride semiconductor layer. In this manner, the first nitride semiconductor layer serves as a carrier supply layer and also the third nitride semiconductor layer serves as a channel layer. Therefore, a high electron mobility transistor (HEMT) with high current driving power and high breakdown voltage can be reliably achieved.

It is also preferable that the inventive semiconductor device further includes a fourth nitride semiconductor layer having a lower oxidation speed than that of the second nitride semiconductor layer between the first nitride semiconductor layer and the insulating oxide layer (i.e., the second nitride semiconductor layer). In this manner, the oxidation is substantially stopped by the fourth nitride semiconductor layer in forming the insulating oxidation layer by oxidizing the second nitride semiconductor layer. That is to say, the fourth nitride semiconductor layer functions as an oxidation stopper (anti-oxidation) layer. Therefore, the thickness of the insulating oxide layer that is to be the gate insulating film can be controlled in a simple manner. In this case, for example, aluminum nitride or the like may be used as a material for the fourth nitride semiconductor layer.

### BRIEF DESCRIPTION OF THE DRAWINGS

FIG. 1 is the cross-sectional view of a semiconductor device according to a first embodiment of the present invention.

FIG. 2 is a graph showing current-voltage characteristics for the semiconductor device according to the first embodiment.

FIG. 3 is a graph showing results of comparison between the respective gate leakage currents in the semiconductor device of the first embodiment and a conventional MOSFET.

FIGS. 4A through 4C are cross-sectional views illustrating respective process steps for fabricating the semiconductor device according to the first embodiment.

FIGS. 5A and 5B are cross-sectional views illustrating respective process steps for fabricating the semiconductor device according to the first embodiment.

FIG. 6 is the cross-sectional view of a semiconductor device according to a second embodiment of the present invention.

FIG. 7 is a graph showing current-voltage characteristics for the semiconductor device according to the second embodiment.

FIGS. 8A through 8C are cross-sectional views illustrating respective process steps for fabricating the semiconductor device according to the second embodiment.

FIGS. 9A and 9B are cross-sectional views illustrating respective process steps for fabricating the semiconductor device according to the second embodiment.

FIG. 10 is a cross-sectional view of a conventional semiconductor device.

### DESCRIPTION OF THE PREFERRED EMBODIMENTS

(First Embodiment)

Hereinafter, a semiconductor device and a method for fabricating the same according to a first embodiment of the present invention will be described with reference to the accompanying drawings.

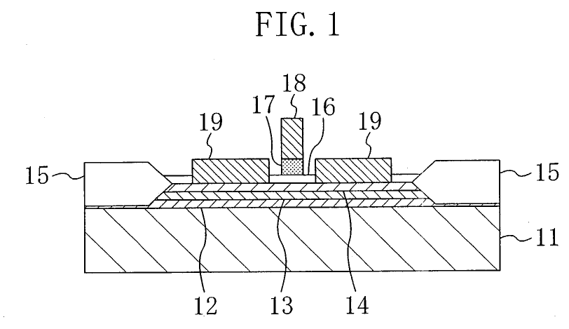

FIG. 1 is the cross-sectional view of the semiconductor device according to the first embodiment. More specifically, FIG. 1 illustrates a cross-sectional structure of a high electron mobility transistor (HEMT) of the insulated gate type, in which a Group III nitride semiconductor is used for an active layer.

As shown in FIG. 1, for example, a buffer layer 12 of, e.g., aluminum nitride (AlN) is formed on a substrate 11 of, e.g., silicon carbide (SiC) to relax the lattice mismatch between the substrate 11 and an epitaxial layer grown on the substrate 11. On the substrate 11, a channel layer 13 of, e.g., gallium nitride and a carrier supply layer 14 of, e.g., n-type aluminum gallium nitride (AlGaN) are formed in this order with the buffer layer 12 interposed between the substrate 11 and the channel layer 13. In this structure, a two-dimensional electron gas layer is formed in part of the upper portion of the channel layer 13 located in the vicinity of the heterointerface between the channel layer 13 and the carrier supply layer 14. The carrier supply layer 14 supplies carriers (i.e., electrons) to the channel layer 13.

On the substrate 11 on which the buffer layer 12, the channel layer 13 and the carrier supply layer 14 are formed, an isolation insulating film 15 is formed so as to reach the buffer layer 12. The isolation insulating film 15 separates transistor regions from each other. An insulating oxide layer 16, obtained by oxidizing a nitride semiconductor, is selectively formed on the carrier supply layer 14 located in each of the transistor regions. More specifically, the insulating oxide layer 16 is formed by oxidizing a nitride semiconductor layer (e.g., a gallium nitride layer) grown on the carrier supply layer 14. That is to say, the insulating oxide layer 16 is formed of gallium oxide (Ga₂O₃).

The first embodiment is characterized in that a metal oxide electrode 17 of, e.g., a tin-doped indium oxide, is formed on the insulating oxide layer 16. Thus, it is possible to prevent the reduction of part of the insulating oxide layer 16 located in the vicinity of the interface between the insulating oxide layer 16 and the metal oxide electrode 17. Accordingly, the insulating film-electrode interface can be kept stable while good insulation properties of the insulating oxide layer 16 can be maintained. On the metal oxide electrode 17, formed is a metal electrode 18 including, e.g., a mutilayer product in which a lower layer made from a platinum (Pt) layer and an upper layer made from a gold (Au) layer are stacked. In the first embodiment, the metal oxide electrode 17 and the metal electrode 18 together form a gate electrode. Furthermore, a pair of source/drain electrodes 19 is formed on both sides of the gate electrode on the carrier supply layer 14 so as to extend in the gate length direction and be in ohmic contact with the carrier supply layer 14. The source drain electrodes 19 are formed from, e.g., a mutilayer product in which a lower layer made from a titanium (Ti) layer and an upper layer made from an aluminum (Al) layer are stacked.

As has been described, in the semiconductor device (HEMT) of the first embodiment, the metal oxide electrode 17 of tin-doped indium oxide is formed on the insulating oxide layer 16, i.e., the gate insulating film formed by oxidizing a nitride semiconductor layer grown on the carrier supply layer 14. In this case, the tin-doped indium oxide is conductive and thus can be used as an electrode material. Moreover, since metals (In and Sn) contained in the metal oxide electrode 17 that is to be a gate electrode has been already oxidized, a metal (Ga) contained in the insulating oxide layer 16 will not be reduced. Furthermore, the oxidation state of In contained in the indium oxide (In₂O₃) which is a main ingredient of the metal oxide electrode 17 is the same as that of Ga contained in the gallium oxide (Ga₂,₃) that forms the insulating oxide layer 16, and the basic unit cell structure of an indium oxide crystal is also the same as that of a gallium oxide crystal. Accordingly, the chemical and structural affinities between the metal oxide electrode 17 and the insulating oxide layer 16 are increased. Therefore, defects, such as oxygen vacancies, are hardly created in the part of the insulating oxide layer 16 located in the vicinity of the interface between the insulating oxide layer 16 and the metal oxide electrode 17 in forming the metal oxide electrode 17. As a result, leakage current caused by the defects is reduced while the insulating film-electrode interface become chemically stable, and therefore a highly reliable gate structure can be achieved.

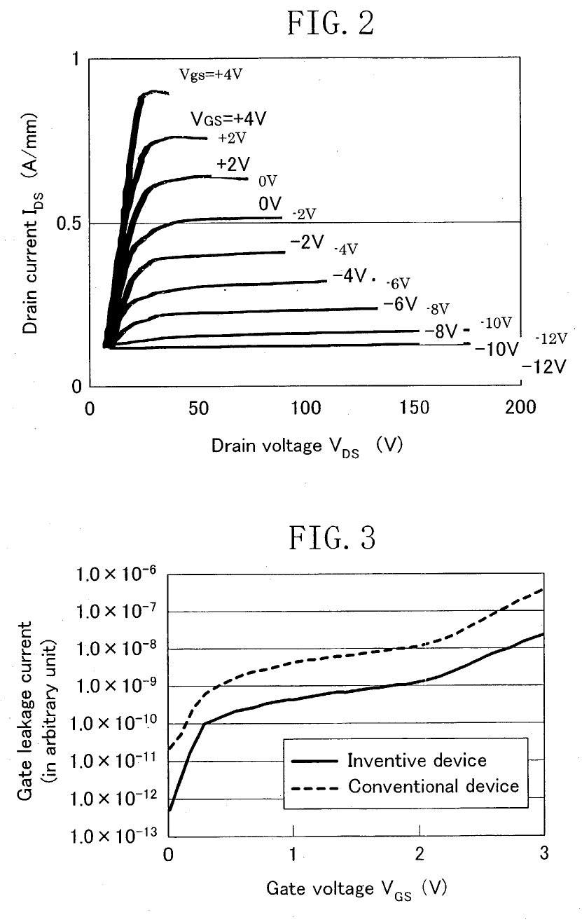

FIG. 2 is a graph showing current-voltage characteristics for the HEMT of the first embodiment. In FIG. 2, the gate voltage level (i.e., the gate-source voltage level) is represented by V_{GS} In the HEMT, gate voltages V_{GS} of 0V, +2V, and +4V are applied in the forward direction (i.e., in the direction in which the gate side has the positive potential) and gate voltages V_{GS} of −2V, −4V, −6V, −9V, −10V, and −12V are applied in the reverse direction (i.e., in the direction in which the gate side has negative potential). Also, in FIG. 2, the abscissa indicates the drain voltage level (i.e., the source-drain voltage level) V_{DS} and the ordinate indicates the drain current level (i.e., the source-drain current level) I_{DS} per unit gate width. As has been described, in the HEMT of the first embodiment, the insulating oxide film 16 to be a gate insulating film exhibits excellent insulation properties and the interface between the metal oxide electrode 17 and the insulating oxide layer 16 exhibits excellent electrical properties and excellent chemical stability. Therefore, as shown in FIG. 2, the drain blocking voltage reaches as high as 200 V or more. Also, with a gate-source voltage V_{GS} of 4V or more applied in the forward direction, no leakage current from the metal oxide layer 17, i.e., no leakage current from the gate electrode is generated. This shows that an HEMT with excellent current-voltage characteristics has been attained.

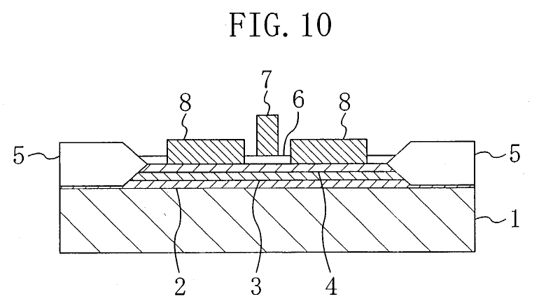

FIG. 3 is a graph showing results of comparison between the respective gate leakage currents in the HEMT (i.e., the inventive HEMT) of the first embodiment and the conventional MOSFET (i.e., an MOSFET in which a metal electrode is formed directly on a gate insulating film) shown in FIG. 10 under the same conditions (e.g., with the same gate size). In FIG. 3, the abscissa indicates the gate voltage level (i.e., gate-source voltage level) V_{GS} and the ordinate indicates the gate leakage current (in arbitrary unit). Also, in FIG. 3, the solid line indicates the gate leakage current in the inventive HEMT and the dashed line indicates the leakage current in the conventional MOSFET. As is evident from FIG. 3, the gate leakage current is suppressed to very low levels in the HEMT of the first embodiment.

Hereinafter, a method for fabricating the semiconductor device of the first embodiment with reference to the accompanying drawings.

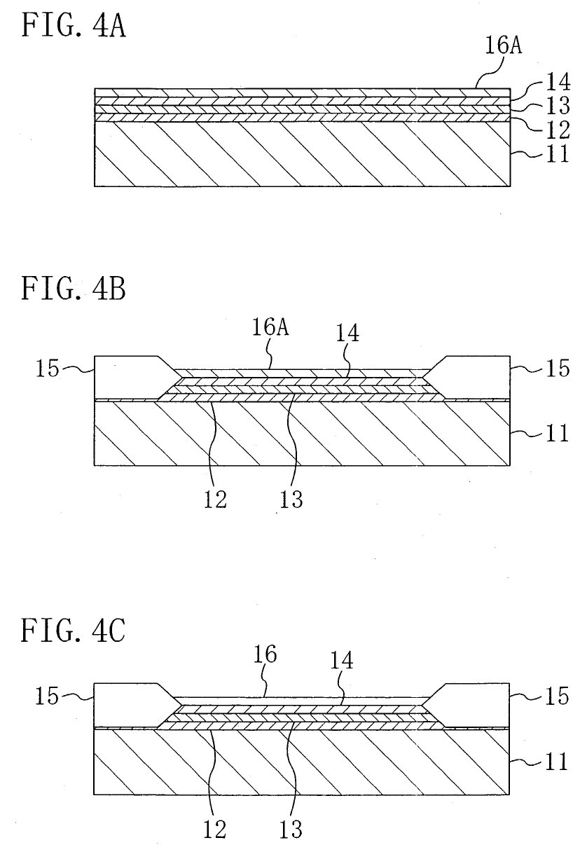

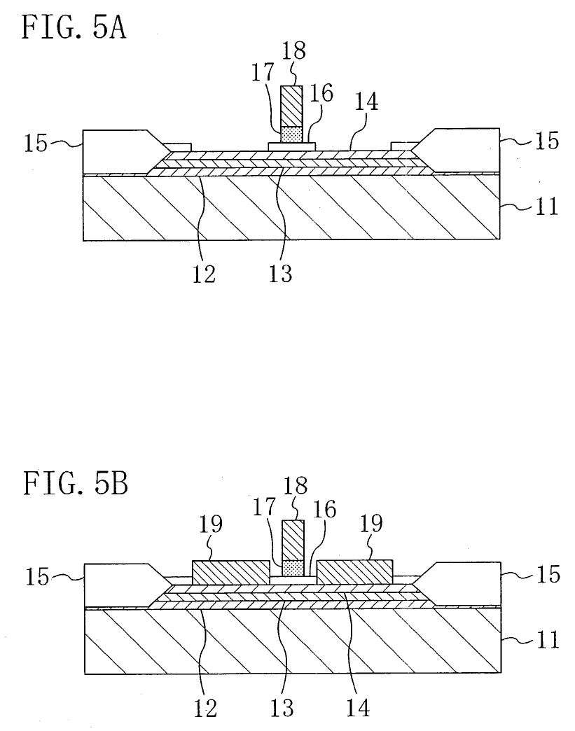

FIGS. 4A through 4C and FIGS. 5A and 5B illustrate fabrication process steps for the semiconductor device of the first embodiment. More specifically, FIGS. 4A through 4C and FIGS. 5A and 5B are cross-sectional views illustrating respective process steps for fabricating the insulated gate type HEMT of FIG. 1.

First, as shown in FIG. 4A, using metal organic chemical vapor deposition (MOCVD), a buffer layer 12 of, e.g., aluminum nitride and with a thickness of about 100 nm; a channel layer 13 of, e.g., gallium nitride and with a thickness of about 3 μm (i.e., 3000 nm); a carrier supply layer 14 of, e.g., n-type aluminum gallium nitride which is doped with silicon (Si) as a dopant, and with a thickness of about 15 nm; and an insulating film forming layer 16A of, e.g., gallium nitride and with a thickness of about 50 to 100 nm are grown in this order on a substrate 11 of, e.g., silicon carbide. That is to say, an epitaxial mutilayer product made of nitride semiconductors is formed on the substrate 11.

Next, a protective film (not shown) of silicon is formed using lithography so as to mask transistor regions, and then the substrate 11 is subjected to thermal oxidation for about 1 to 2 hours in an oxidation atmosphere. Thus, as shown in FIG. 4B, an isolation insulating film 15 is selectively formed on the substrate 11 on which the epitaxial mutilayer product is formed.

Next, the protective film is removed, and then the substrate 11 is subjected to thermal oxidation for several minutes in an oxidation atmosphere. Thus, as shown in FIG. 4C, an insulating oxide layer 16 is formed from the insulating film forming layer 16A located in the upper portion of the epitaxial mutilayer product.

Next, a conductive metal oxide film of tin-doped indium oxide and with a thickness of about 20 nm is deposited on the insulating oxide layer 16 using, e.g., sputtering, and a multilayer metal film including a platinum layer with a thickness of about 50 nm and a gold layer with a thickness of 200 nm is subsequently deposited on the conductive metal oxide film. Thereafter, the deposited multilayer metal film and conductive metal oxide film, i.e., gate electrode forming conductive films, are patterned using lithography and dry etching so that a metal oxide electrode 17 is formed on the insulating oxide layer 16 and a metal electrode 18 is formed on the metal oxide electrode 17, as shown in FIG. 5A. In this case, this multilayer structure including the metal oxide electrode 17 and the metal electrode 18 forms a gate electrode. Thereafter, parts of the insulating oxide layer 16 which are located on both sides of the gate electrode in the gate length direction are selectively etched, thereby forming a pair of openings in the insulating oxide layer 16. Thus, parts of the carrier supply layer 14 are exposed through the pair of openings. Then, a multilayer metal film including a titanium layer with a thickness of about 20 nm and an aluminum layer with a thickness of about 200 nm is deposited by, e.g., sputtering on the parts of the carrier supplying layer 14 exposed through the pair of openings. Subsequently, the deposited multilayer metal film is patterned using lithography and dry etching, thereby forming a pair of source/drain electrodes 19 so that the electrodes are connected with the carrier supply layer 14, as shown in FIG. 5B.

As has been described, in the method for fabricating the HEMT of the first embodiment, the insulating film forming layer 16A of gallium nitride is subjected to thermal oxidation, thereby forming the insulating oxide layer 16 on the upper surface of the epitaxial multilayer body on the substrate 11. Thereafter, the metal oxide electrode 17 of indium-tin alloy oxide (tin-doped indium oxide) is formed directly on the insulating oxide layer 16, i.e., directly on the gate insulting film, and then the metal electrode 18 is formed on the metal oxide electrode 17.

That is to say, according to the first embodiment, the insulating oxide layer 16 formed by oxidizing a nitride semiconductor itself is used as a gate insulating film and the metal oxide electrode 17 is used as a gate electrode (more precisely, as the lower portion of a gate electrode). More specifically, a metal contained in the metal oxide electrode 17 has already become an oxide, and therefore it is possible to prevent the metal oxide (Ga oxide) of the insulating oxide layer 16 to be a gate insulating film from being reduced by an electrode material. As a result, defects, such as oxygen vacancies, in the gate insulating film to be created when a metal film is deposited directly on the insulating oxide layer 16, i.e., directly on the gate insulating film, are not created. Accordingly, the generation of leakage current due to such defects can be prevented while electrical properties of the insulating film-electrode interface can be stabilized. Therefore, the reliability of the gate insulating film can be improved.

Note that in the first embodiment, the conductivity of the metal oxide electrode 17, i.e., the conductivity of the gate electrode, can be set at a desired value by adjusting the composition ratio of indium to tin in the metal oxide electrode 17.

Furthermore, in the first embodiment, a tin-doped indium oxide is used as a material for the metal oxide electrode 17. However, even if indium oxide, indium-tin alloy oxide, rhodium oxide, or the like is used instead of the tin-doped indium oxide, the same effects can be attained. For example, the oxidation state of Rh contained in dirhodium trioxide (Rh₂O₃) which is a main ingredient of the rhodium oxide is the same as that of Ga contained in the gallium oxide (Ga₂O₃) while the basic unit cell structure of a dirhodium trioxide crystal is the same as that of a gallium oxide crystal. Thus, even if rhodium oxide is used as a material for the metal oxide electrode 17, the chemical and structural affinities between the metal oxide electrode 17 and the insulating oxide layer 16 are increased as in this embodiment in which indium oxide is used as a material for the metal oxide electrode 17. Therefore, an electrically and chemically stable insulating film-electrode interface can be achieved.

In the first embodiment, the thickness of the insulating oxide layer 16 can be controlled by adjusting the time duration for subjecting the substrate 11 to thermal oxidation, i.e., the time duration for heating the insulating film forming layer 16A in the process step shown in FIG. 4C. For example, the insulating film forming layer 16A with a thickness of about 50 to 100 nm may be entirely oxidized to form the insulating oxide layer 16 with about the same thickness as the insulating film forming layer 16A. As another option, only the upper portion of the insulating film forming layer 16A may be oxidized so that the insulating oxide layer 16 is formed with a non-oxidized portion of the insulating film forming layer 16A (i.e., the gallium nitride layer) left under the insulating oxide layer 16. As still another option, with the thickness of the insulating film forming layer 16A reduced to, e.g., about 5 to 10 nm, the thin insulating film forming layer 16A may be entirely oxidized to form the insulating oxide layer 16 with about the same thickness as that of the thin insulating film forming layer 16A. In any case, the insulating oxide layer 16 is formed on the carrier supply layer 14 by oxidizing the insulating film forming layer 16A. Thus, the film quality of the insulating oxide layer 16, i.e., the film quality of the gate insulating film, is improved while the contact interface between the insulating oxide layer 16 and the carrier supply layer 14 (or the non-oxidized portion of the insulating film forming layer 16A) located under the insulating oxide layer 16 becomes very clean.

Now, the oxidation speed of the insulating film forming layer 16A of gallium nitride (GaN) is compared to that of the carrier supply layer 14 of aluminum gallium nitride (AlGaN) in the thermal oxidation. When the composition ratio of Al in aluminum gallium nitride is 0.3, the oxidation speed of gallium nitride is twice as high as that of aluminum gallium nitride. Therefore, it is possible to selectively oxidize the insulating film forming layer 16A to form the insulating oxide layer 16 while suppressing oxidation of the carrier supply layer 14 located under the insulating oxide layer 16. Moreover, since the energy gap of aluminum gallium nitride is larger than that of gallium nitride, the carrier supply layer 14 can be used as a potential barrier layer.

In the first embodiment, gallium nitride (GaN) is used as a material for the insulating film forming layer 16A i.e., a layer to be oxidized, for forming the insulating oxide layer 16. However, materials for the insulating film forming layer 16A are not limited to gallium nitride (GaN), but may includes other gallium nitride base semiconductors of which a quality insulating oxide layer can be formed. For example, aluminum gallium nitride, indium gallium nitride (InGaN), indium aluminum gallium nitride (InAlGaN), or the like may be used.

In the first embodiment, the insulating film forming layer 16A is subjected to thermal oxidation, thereby forming the insulating oxide film 16. However, instead of thermal oxidation, other techniques by which a quality oxide film with excellent insulation properties can be formed may be used. For example, the insulating film forming layer 16A may be subjected to ion implantation, plasma doping, or the like, thereby forming the insulating oxide layer 16.

In the first embodiment, the HEMT including the channel layer 13 of gallium nitride and the carrier supply layer 14 of n-type aluminum gallium nitride is formed as a semiconductor device including an insulated gate. However, this embodiment is not limited to this structure, but an HEMT or a FET in which an active layer is formed of, e.g., gallium nitride, aluminum gallium nitride, indium gallium nitride, indium aluminum gallium nitride, or the like may be formed. Note that it is normally necessary to select materials for the channel layer 13 and the carrier supply layer 14 so that the energy gap of the carrier supply layer 14 is larger than that of the channel layer 13 when an HEMT is formed.

In the first embodiment, silicon carbide is used as a material for the substrate 11. However, instead of silicon carbide, other materials on which a Group III nitride semiconductor layer such as the channel layer 13 can be epitaxially grown may be used as substrate materials. For example, gallium nitride, sapphire (Al₃O₃) may be used.

In the first embodiment, metal materials for the metal electrode 18 and the source/drain electrodes 19 are not particularly limited. However, if the metal electrode 18 formed on the metal oxide electrode 17 is made of a precious metal such as platinum, palladium, iridium, ruthenium, rhodium, or the like, as in this embodiment, the following effects can be attained (note that the metal electrode 18 of a multilayer body including a platinum layer and a gold layer is used in this embodiment). Since these precious metals have oxidation resistance, the occurrence of an oxidation-reduction reaction can be prevented between the metal electrode 18 and the metal oxide electrode 17 in forming the metal electrode 18. Therefore, a fine interface is formed between the metal electrode 18 and the metal oxide electrode 17. Accordingly, it is possible to avoid the situation in which the metal oxide electrode 17 is reduced by the metal electrode 18 and then the reduced metal oxide electrode 17 is re-oxidized by the insulating oxide layer 16. In other words, it is possible to avoid the situation in which the insulating oxide layer 16 to be the gate insulating film is reduced by the metal oxide electrode 17. Thus, a highly reliable multilayer gate structure with small leakage current can be achieved.

In the first embodiment, the metal oxide electrode 17 and the metal electrode 18 are formed to be stacked on the insulating oxide layer 16, openings are formed in the insulating oxide layer 16, and then the source/drain electrodes 19 are formed on the carrier supply layer 14. However, instead of this order of the process steps, the source/drain electrodes 19 may be formed before the metal oxide electrode 17 and the metal electrode 18.

(Second Embodiment)

Hereinafter, a semiconductor device and a method for fabricating the same according to a second embodiment of the present invention will be described with reference to the accompanying drawings.

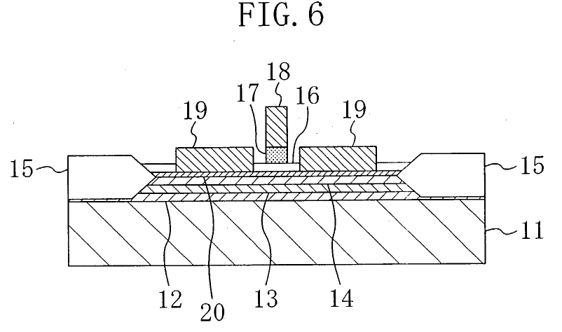

FIG. 6 is the cross-sectional view of a semiconductor device according to the second embodiment. More specifically, FIG. 6 illustrates a cross-sectional structure of an HEMT of the insulated gate type, in which a Group III nitride semiconductor is used for an active layer. In FIG. 6, the same members as those of the semiconductor device of the first embodiment shown in FIG. 1 are identified by the same reference numerals.

As shown in FIG. 6, a buffer layer 12 of, e.g., aluminum nitride, a channel layer 13 of, e.g., gallium nitride, a carrier supply layer 14 which is formed of, e.g., n-type aluminum gallium nitride and supplies carriers (electrons) to the channel layer 13, and an oxidation stopper (anti-oxidation) layer 20 of aluminum nitride are formed in this order on a substrate 11 of, e.g., silicon carbide.

On the substrate 11 on which the buffer layer 12, the channel layer 13, the carrier supply layer 14, and the oxidation stopper layer 20 are formed, an isolation insulating film 15 is formed so as to reach the buffer layer 12. The isolation insulating film 15 separates transistor regions from each other. An insulating oxide layer 16, obtained by oxidizing a nitride semiconductor, is selectively formed on part of the oxidation stopper layer 20 located in each of the transistor regions. More specifically, the insulating oxide layer 16 is formed by oxidizing a nitride semiconductor layer (e.g., a gallium nitride layer) grown on the oxidation stopper layer 20. That is to say, the insulating oxide layer 16 is formed of gallium oxide (Ga₂O₃).

The second embodiment is characterized in that a metal oxide electrode 17 of, e.g., iridium oxide, is formed on the insulating oxide layer 16. Thus, it is possible to prevent the reduction of part of the insulating oxide layer 16 located in the vicinity of the interface between the insulating oxide layer 16 and the metal oxide electrode 17. Accordingly, insulating film-electrode interface can be kept stable while good insulation property of the insulating oxide layer 16 can be maintained. On the metal oxide electrode 17, formed is a metal electrode 18 including, e.g., a mutilayer product in which a lower layer made from a platinum layer and an upper layer made from a gold layer are stacked. In the second embodiment, the metal oxide electrode 17 and the metal electrode 18 together form a gate electrode. Furthermore, a pair of source drain electrodes 19 is formed on both sides of the gate electrode on the oxidation stopper layer 20 so as to extend in the gate length direction and be in ohmic contact with the oxidation stopper layer 20. The source drain electrodes 19 are formed from, e.g., a multilayer body in which a lower layer made from a titanium layer and an upper layer made from an aluminum layer are stacked.

As has been described, in the HEMT of the second embodiment, the metal oxide electrode 17 of iridium oxide is formed on the insulating oxide layer 16, i.e., the gate insulating film formed by oxidizing a nitride semiconductor layer grown on the oxidation stopper layer 20 of aluminum nitride. In this case, the iridium oxide is conductive and thus can be used as an electrode material. Moreover, since a metal (Ir) contained in the metal oxide electrode 17 that is to be a gate electrode has been already oxidized, a metal (Ga) contained in the insulating oxide layer 16 will not be reduced.

The oxidation state (i.e., the oxidation number) of the metal Ir contained in the metal oxide electrode 17 differs from that of the metal Ga contained in the insulating oxide layer 16 and the basic unit cell structure of an iridium oxide crystal also differs from that of a gallium oxide crystal. Accordingly, the structural affinity between the metal oxide electrode 17 and the insulating oxide layer 16 is lower than the structural affinity therebetween in the case in which indium oxide, rhodium oxide, or the like is used as a main ingredient of the metal oxide electrode 17 as in the first embodiment. Therefore, defects, such as interstitial gallium atoms, due to oxygen vacancies may be created in the insulating oxide layer 16.

However, the iridium oxide used as a material for the metal oxide electrode 17 in this embodiment has excellent oxidation resistance and serves as a diffusion barrier against interstitial gallium atoms. Therefore, even if interstitial gallium atoms are generated due to a reduction reaction in the insulating oxide layer 16 that is to be a gate insulating film, the interstitial gallium atoms do not diffuse but stay within the insulating oxide layer 16, and are finally re-oxidized. Accordingly, also in the second embodiment, it is possible to make an electrically and chemically stable insulating film-electrode interface (i.e., the electrically and chemically stable interface between the metal oxide electrode 17 and the insulating oxide layer 16) can be achieved while a highly reliable gate structure with small gate leakage current can be obtained, as in the first embodiment.

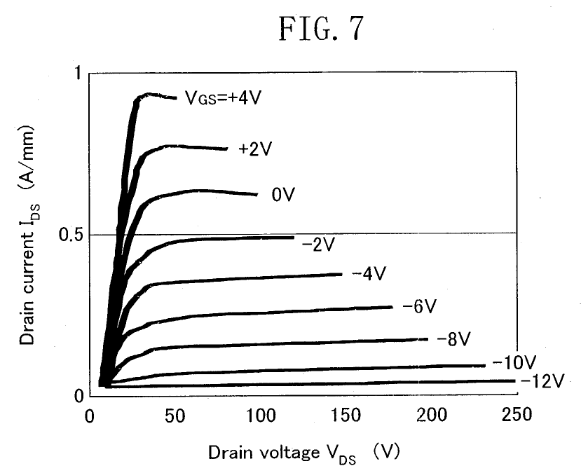

FIG. 7 is a graph showing current-voltage characteristics for the HEMT of the second embodiment. In FIG. 7, the gate voltage level (i.e., the gate-source voltage level) is represented by V_{GS}. In the HEMT, gate voltages V_{GS} of 0V, +2V, and +4V are applied in the forward direction (i.e., in the direction in which the gate side has the positive potential) and gate voltages V_{GS} of −2V, −4V, −6V, −8V, −10V, and −12V are applied in the reverese direction (i.e., in the direction in which the gate side has negative potential). Also, in FIG. 7, the abscissa indicates the drain voltage level (i.e., the source-drain voltage level) V_{DS} and the ordinate indicates the drain current level (i.e., the source-drain current level) I_{DS} per each unit gate width. As has been described, in the EMT of the second embodiment, the insulating oxide film 16 to be a gate insulating film exhibits excellent insulation properties while the interface between the metal oxide electrode 17 and the insulating oxide layer 16 exhibits excellent electrical properties and excellent chemical stability. Therefore, the drain blocking voltage reaches as high as 200 V or more, as shown in FIG. 7. Moreover, with a gate-source voltage VGS of 4V or more applied in the forward direction, no leakage current from the metal oxide electrode 17, i.e., no leakage current from the gate electrode is generated. This shows that an HEMT with excellent current-voltage characteristics has been achieved.

Hereinafter, a method for fabricating the semiconductor device of the second embodiment with reference to the accompanying drawings.

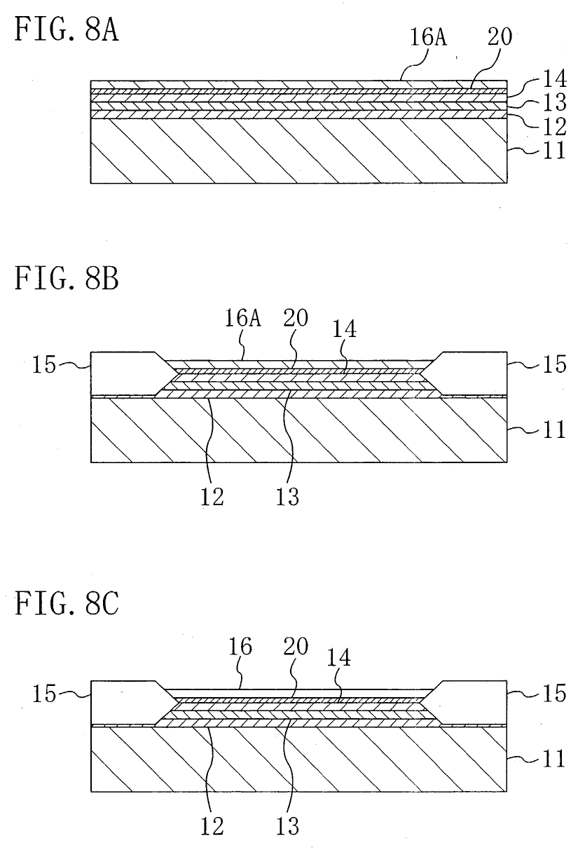

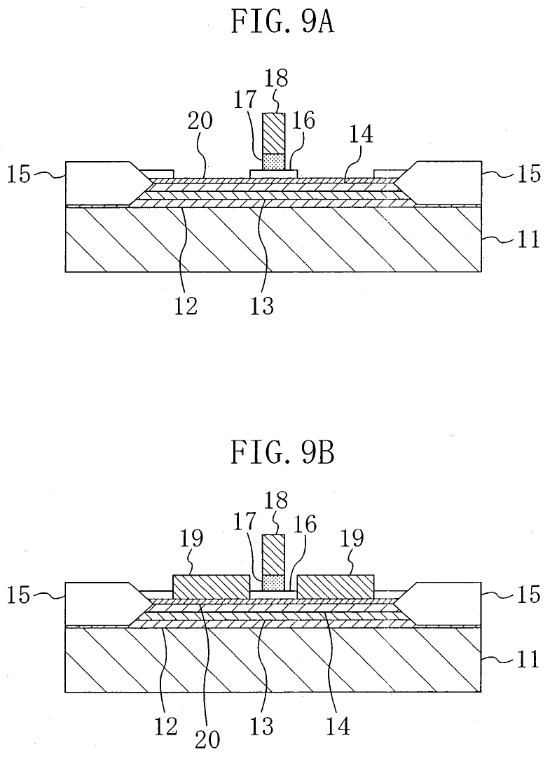

FIGS. 8A through 8C and FIGS. 9A and 9B illustrate fabrication process steps for the semiconductor device of the second embodiment. More specifically, FIGS. 8A through 8C and FIGS. 9A and 9B are cross-sectional views illustrating respective process steps for fabricating the insulated gate type HEMT of FIG. 6.

First, as shown in FIG. 8A, using MOCVD, a buffer layer 12 of, e.g., aluminum nitride and with a thickness of about 100 nm; a channel layer 13 of, e.g., gallium nitride and with a thickness of about 3 μm (i.e., 3000 nm); a carrier supply layer 14 of, e.g., n-type aluminum gallium nitride which is doped with silicon (Si) as a dopant, and with a thickness of about 15 nm; an oxidation stopper layer 20 of, e.g., aluminum nitride and with a thickness of about 20 to 50 nm; and an insulating film forming layer 16A of, e.g., gallium nitride and with a thickness of about 50 to 100 nm are grown in this order on a substrate 11 of, e.g., silicon carbide. That is to say, an epitaxial mutilayer product made of nitride semiconductors is formed on the substrate 11.

Next, a protective film (not shown) of silicon is formed using lithography so as to mask transistor regions, and then the substrate 11 is subjected to thermal oxidation for about 1 to 2 hours in an oxidation atmosphere. Thus, as shown in FIG. 8B, an isolation insulating film 15 is selectively formed on the substrate 11 on which the epitaxial mutilayer product is formed.

Next, the protective film is removed, and then the substrate 11 is subjected to thermal oxidation for several minutes in an oxidation atmosphere. Thus, as shown in FIG. 8C, an insulating oxide layer 16 is formed from the insulating film forming layer 16A located in the upper portion of the epitaxial mutilayer product. Also in the second embodiment, the thickness of the insulating oxide layer 16 can be controlled by adjusting the time duration for heating the insulating film forming layer 16A, as in the first embodiment. In this case, the oxidation speed of aluminum nitride forming the oxidation stopper layer 20 is very low, i.e., about one fiftieth than that of gallium nitride forming the insulating film formation layer 16A. It is, therefore, supposed that thermal oxidation of the insulating film forming layer 16A is substantially stopped at the oxidation stopper layer 20. Accordingly, even if the insulating film forming layer 16A is entirely oxidized, the carrier supply layer 14 is not oxidized and thus the thickness of the insulating oxide layer 16 is substantially controlled with the thickness of the insulating film forming layer 16A. As a result, it is possible to greatly improve easiness of controlling the film thickness of the gate insulating film, i.e., the film thickness of the insulating oxide layer 16, which greatly influence operation properties of a device including an insulated gate.

Next, a conductive metal oxide film of iridium oxide and with a thickness of about 20 nm is deposited on the insulating oxide layer 16 using, e.g., sputtering, and a multilayer metal film including a platinum layer with a thickness of about 50 nm and a gold layer with a thickness of about 200 nm is subsequently deposited on the conductive metal oxide film. Then, the deposited multilayer metal film and conductive metal oxide film, i.e., gate electrode forming conductive films, are patterned using lithography and dry etching. Thus, as shown in FIG. 9A, a metal oxide electrode 17 is formed on the insulating oxide layer 16 and a metal electrode 18 is formed on the metal oxide electrode 17. In this case, this multilayer structure of the metal oxide electrode 17 and the metal electrode 18 forms the gate electrode. Thereafter, parts of the insulating oxide layer 16 which are located on both sides of the gate electrode in the gate length direction are selectively etched, thereby forming a pair of openings in the insulating oxide layer 16. Thus, parts of the oxidation stopper layer 20 are exposed through the pair of openings. Then, a multilayer metal film including a titanium layer with a thickness of about 20 nm and an aluminum layer with a thickness of about 200 nm is deposited by, e.g., sputtering on the parts of the oxidation stopper layer 20 exposed through the pair of openings. Subsequently, the deposited multilayer metal film is patterned using lithography and dry etching, thereby forming a pair of source/drain electrodes 19 so that the electrodes are connected with the oxidation stopper layer 20, as shown in FIG. 9B.

As has been described, in the method for fabricating the HEMT of the second embodiment, the insulating film forming layer 16A of gallium nitride is subjected to thermal oxidation, thereby forming the insulating oxide layer 16 on the upper surface of the epitaxial multilayer body on the substrate 11. Thereafter, the metal oxide electrode 17 of iridium oxide is formed directly on the insulating oxide layer 16, i.e., directly on the gate insulting film, and then the metal electrode 18 is formed on the metal oxide electrode 17.

That is to say, according to the second embodiment, the insulating oxide layer 16 formed by oxidizing a nitride semiconductor itself is used as a gate insulating film and the metal oxide electrode 17 is used as a gate electrode (more precisely, as the lower portion of a gate electrode). More specifically, a metal contained in the metal oxide electrode 17 has already become an oxide, and therefore it is possible to prevent the metal oxide (Ga oxide) of the insulating oxide layer 16 to be a gate insulating film from being reduced by an electrode material. As a result, defects, such as oxygen vacancies, in the gate insulating film caused when a metal film is deposited directly on the insulating oxide layer 16, i.e., directly on the gate insulating film, are not created. Accordingly, the generation of leakage current due to such defects can be prevented while electrical properties of the insulating film-electrode interface can be stabilized. Therefore, the reliability of the gate insulating film can be improved.

In the second embodiment, iridium oxide is used as a material for the metal oxide electrode 17. However, even if ruthenium (Ru) oxide, tin oxide, or the like is used instead of the iridium oxide, the same effects can be attained.

In the second embodiment, the insulating film forming layer 16A is entirely oxidized to form the insulating oxide layer 16 with the almost same thickness as that of the insulating film forming layer 16A in the process step shown in FIG. 8C. However, instead of this process step, only the upper portion of the insulating film forming layer 16A may be oxidized so that the insulating oxide layer 16 is formed with a non-oxidized portion of the insulating film forming layer 16A (i.e., the gallium nitride layer) left under the insulating oxide layer 16. The thickness of the insulating film 16A is about 50 to 100 nm in this embodiment. However, the thickness of the insulating film forming layer 16A is not particularly limited, but may be reduced to, e.g., about 5 to 10 nm. In any case, the insulating oxide layer 16 is formed on the oxidation stopper layer 20 by oxidizing the insulating film forming layer 16A. Thus, the film quality of the insulating oxide layer 16, i.e., the film quality of the gate insulating film, is improved while the contact interface between the insulating oxide layer 16 and the oxidation stopper layer 20 (or the non-oxidized portion of the insulating film forming layer 16A) located under the insulating oxide layer 16 becomes very clean.

In the second embodiment, aluminum nitride is used as a material for the oxidation stopper layer 20. However, materials for the oxidation stopper layer 20 are not limited to aluminum nitride, but may include, e.g., gallium-containing or indium-containing aluminum nitride, or the like. In order to further reduce the oxidation speed of the oxidation stopper layer 20, however, it is preferable to relatively increase the composition ratio of aluminum in the oxidation stopper layer 20.

In the second embodiment, gallium nitride is used as a material for the insulating film forming layer 16A, i.e., a layer to be oxidized, for forming the insulating oxide layer 16. However, materials for the insulating film forming layer 16A are not limited to gallium nitride, but may includes other gallium nitride base semiconductors of which a quality insulating oxide layer can be formed. For example, aluminum gallium nitride, indium gallium nitride, indium aluminum gallium nitride, or the like may be used.

In the second embodiment, the insulating film forming layer 16A is subjected to thermal oxidation, thereby forming the insulating oxide film 16. However, instead of thermal oxidation, other techniques by which a quality oxide film with excellent insulation properties can be formed may be used. For example, the insulating film forming layer 16A may be subjected to ion implantation, plasma doping, or the like, thereby forming the insulating oxide layer 16.

In the second embodiment, the HEMT including the channel layer 13 of gallium nitride and the carrier supply layer 14 of n-type aluminum gallium nitride is formed as a semiconductor device including an insulated gate. However, this embodiment is not limited to this structure, but an HEMT or a FET in which an active layer is formed of, e.g., gallium nitride, aluminum gallium nitride, indium gallium nitride, indium aluminum gallium nitride, or the like may be formed. Note that it is normally necessary to select materials for the channel layer 13 and the carrier supply layer 14 so that the energy gap of the carrier supply layer 14 is larger than that of the channel layer 13 when an HEMT is formed.

In the second embodiment, silicon carbide is used as a material for the substrate 11. However, instead of silicon carbide, other materials on which a Group III nitride semiconductor layer such as the channel layer 13 can be epitaxially grown may be used as substrate materials. For example, gallium nitride, sapphire (Al₃O₃) or the like may be used.

In the second embodiment, metal materials for the metal electrode 18 and the source/drain electrodes 19 are not particularly limited. However, if the metal electrode 18 formed on the metal oxide electrode 17 is made of a precious metal such as platinum, palladium, iridium, ruthenium, rhodium, or the like, as in this embodiment, the following effects can be attained (note that the metal electrode 18 of a multilayer body including a platinum layer and a gold layer is used in this embodiment). Since these precious metals have oxidation resistance, the occurrence of an oxidation-reduction reaction can be prevented between the metal electrode 18 and the metal oxide electrode 17 in forming the metal electrode 18. Therefore, a fine interface is formed between the metal electrode 18 and the metal oxide electrode 17. Accordingly, it is possible to avoid the situation in which the metal oxide electrode 17 is reduced by the metal electrode 18 and then the reduced metal oxide electrode 17 is re-oxidized by the insulating oxide layer 16. In other words, it is possible to avoid the situation in which the insulating oxide layer 16 to be the gate insulating film is reduced by the metal oxide electrode 17. Thus, a highly reliable multilayer gate structure with small leakage current can be achieved.

In the second embodiment, the metal oxide electrode 17 and the metal electrode 18 are formed to be stacked on the insulating oxide layer 16, openings are formed in the insulating oxide layer 16, and then the source/drain electrodes 19 are formed on the oxidation stopper layer 20. However, instead of this order of the process steps, the source/drain electrodes 19 may be formed before the metal oxide electrode 17 and the metal electrode 18.

What is claimed is:

1. A semiconductor device comprising:
an insulating oxide layer formed by oxidizing a nitride semiconductor; and
an electrode formed of a conductive metal oxide on the insulating oxide layer.

2. The semiconductor device of claim 1, wherein the conductive metal oxide is indium oxide or indium-tin alloy oxide.

3. The semiconductor device of claim 1, wherein the conductive metal oxide is rhodium oxide.

4. The semiconductor device of claim 1, wherein the conductive metal oxide is iridium oxide, ruthenium oxide, or tin oxide.

5. The semiconductor device of claim 1, further comprising a metal layer formed on the electrode.

6. The semiconductor device of claim 5, wherein the metal layer is formed of a precious metal.

7. The semiconductor device of claim 6, wherein the precious metal is platinum, palladium, iridium, ruthenium, or rhodium.
